(19) United States
(12) Patent Application Publication
(10) Pub. No.: US 2024/0008169 A1
(43) Pub. Date: Jan. 4, 2024

(54) ELECTRONIC DEVICE

(71) Applicant: ASUSTeK COMPUTER INC., Taipei (TW)

(72) Inventors: Meng-Feng Lin, Taipei (TW); Tung-Yun Kao, Taipei (TW); Chao-Kai Wu, Taipei (TW); Huan-Wen Chen, Taipei (TW); Cheng-Yen Lin, Taipei (TW); Jian-Jia Li, Taipei (TW)

(21) Appl. No.: 17/989,742

(22) Filed: Nov. 18, 2022

(30) Foreign Application Priority Data
Jul. 4, 2022 (TW) 111125025

(51) Int. Cl. H05K 1/02; G09G 3/36; G09G 3/3208; G06F 1/16

(52) U.S. Cl. CPC H05K 1/0251; G09G 3/36; G09G 3/3208; G06F 1/1633

(57) ABSTRACT

An electronic device is provided in this disclosure. The electronic device includes a display panel, a transmission line, a universal motherboard, and an optional panel power management module. The display panel is a first type display panel or a second type display panel. The transmission line is a first transmission line or a second transmission line. The universal motherboard is connected to the first type display panel through the first transmission line, or connected to the second type display panel through the second transmission line. When the display panel is the first type display panel, the panel power management module is connected to the universal motherboard and the first type display panel through the first transmission line, so that the panel power management module provides power management required for the first type display panel according to the universal motherboard.

### CROSS-REFERENCE TO RELATED APPLICATION

The disclosure claims the priority benefit of Taiwan disclosure Ser. No. 111125025, filed on Jul. 4, 2022. The entirety of the above-mentioned patent disclosure is hereby incorporated by reference herein and made a part of the specification.

### BACKGROUND OF THE INVENTION

### Field of the Invention

The disclosure relates to an electronic device which has a universal motherboard and selects a panel power management module according to a type of a display panel.

### Description of the Related Art

There are various existing notebook computer screens. At present, in-plane-switching (IPS) panels and organic light-emitting diode (OLED) panels are commonly used, and have their own advantages. In order to adapt to different usage scenarios, these two types of panels are used as the notebook computer screens. However, such a design usually requires different motherboards corresponding to different types of panels, because IPS panel and OLED panel are completely different display screens.

The IPS panel is made of an inorganic material and includes two parallel glass substrates, with transistors placed below. The IPS generates colors through the interaction between backlighting and filters of the glass substrates. The OLED panel is made of an organic material and includes organic light-emitting diodes, to emit light through a voltage action of an organic coating and a glass substrate. The two types of panels have completely different structures. The biggest difference is that the OLED panel requires a power management circuit and a peripheral signal. Therefore, the motherboard suitable for the OLED panel has a built-in power management integrated circuit (PMIC) design, and the motherboard suitable for the IPS panel does not need this design. Therefore, different types of panels need to have respective motherboard designs.

### BRIEF SUMMARY OF THE INVENTION

According to an aspect of this disclosure, an electronic device is provided. The electronic device includes a display panel, a transmission line, and a universal motherboard. The display panel is a first type display panel or a second type display panel. The transmission line is a first transmission line or a second transmission line. The universal motherboard is connected to the first type display panel through the first transmission line, or connected to the second type display panel through the second transmission line. The electronic device further includes a panel power management module, and when the display panel is the first type display panel, the panel power management module is connected to the universal motherboard and the first type display panel through the first transmission line, so that the panel power management module provides power management required for the first type display panel according to the universal motherboard.

To sum up, the electronic device in the disclosure uses a universal motherboard to match different transmission lines without replacing the motherboard, so that the same motherboard is compatible with display panels of two different architectures. In this way, an area of the motherboard is optimized. In addition, with an independent design of the panel power management module, the motherboard is applicable to a wider range. Therefore, the area of the motherboard has higher utilization, and subsequently designed models are also allowed to share the panel power management module, so that different models have better commonality.

### BRIEF DESCRIPTION OF THE DRAWINGS

FIG. 1 is a schematic block diagram of an electronic device having a first type display panel according to an embodiment of the disclosure.

FIG. 2 is a schematic block diagram of an electronic device having a second type display panel according to an embodiment of the disclosure.

FIG. 3 is a schematic structural diagram of a first transmission line according to an embodiment of the disclosure.

FIG. 4 is a schematic structural diagram of a second transmission line according to an embodiment of the disclosure.

### DETAILED DESCRIPTION OF THE EMBODIMENTS

However, the preferred embodiments are only described as examples and are not intended to limit the protection scope of the disclosure. In addition, some elements or structures may be omitted in the drawings in the embodiments, to clearly show technical features of the disclosure. Throughout the drawings, the same reference numbers will be used to represent the same or similar elements. It needs be understood that although the terms “first”, “second”, and the like are used herein to describe various elements, components, circuits, or functions, these elements, components, circuits, and/or functions should not be limited by these terms. The terms are only used to distinguish one element, component, circuit or function from another element, component, circuit or function.

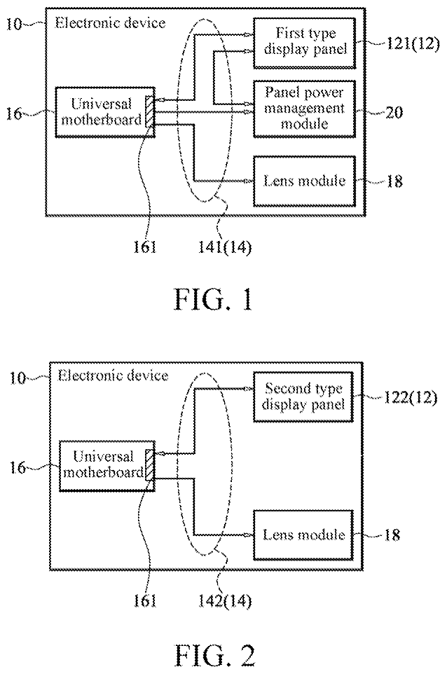

Referring to FIG. 1 and FIG. 2 together, an electronic device 10 includes a display panel 12, a transmission line 14, a universal motherboard 16, a lens module 18, and an optional panel power management module (that is, PMIC) 20. In the electronic device 10, the display panel 12 is one of a first type display panel 121 or a second type display panel 122. The transmission line 14 is one of a first transmission line 141 or a second transmission line 142. The universal motherboard 16 is connected to the first type display panel 121 through the first transmission line 141, or connected to the second type display panel 122 through the second transmission line 142. The lens module 18 is connected to the universal motherboard 16 through the first transmission line 141 or the second transmission line 142. When the display panel 12 is the first type display panel 121, the electronic device 10 uses the panel power management module 20. The panel power management module 20 is connected to the universal motherboard 16 and the first type display panel 121 through the first transmission line 141, so that the panel power management module 20 provides power management required for the first type display panel 121 according to the universal motherboard 16.

In an embodiment, the electronic device 10 is a notebook computer, or other electronic devices having a display panel, but the disclosure is not limited thereto.

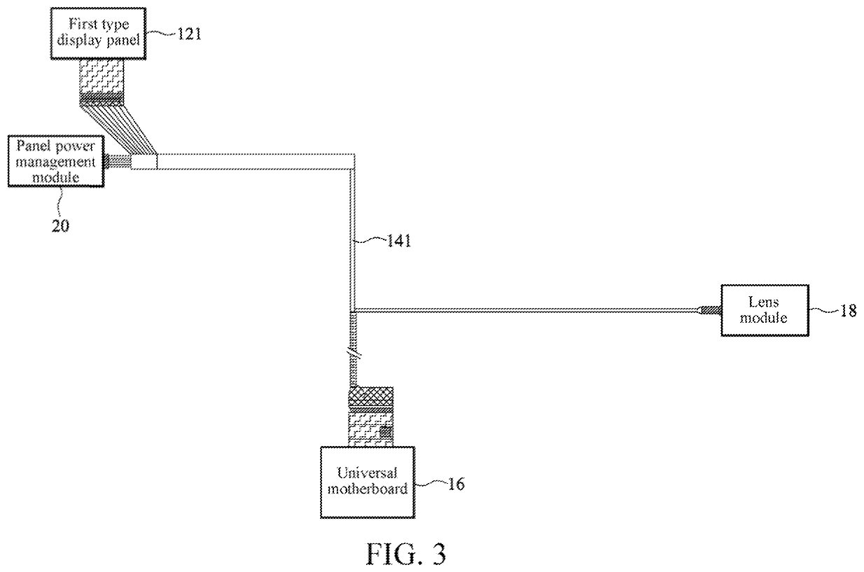

Because the first type display panel 121 is a display panel 12 that requires power management provided by the panel power management module 20, in an embodiment, the first type display panel 121 is an organic light-emitting diode (OLED) panel. As shown in FIG. 1 and FIG. 3, the electronic device 10 includes the first type display panel 121, the first transmission line 141, the universal motherboard 16, the lens module 18, and the panel power management module 20. The universal motherboard 16 is connected to the first type display panel 121, the lens module 18, and the panel power management module 20 through the first transmission line 141, and the panel power management module 20 is also connected to the first type display panel 121 through the first transmission line 141. The first transmission line 141 is an embedded display port (EDP) transmission line, and the universal motherboard 16 is provided with an embedded display port connector 161 correspondingly, so that the first transmission line 141 is connected to the embedded display port connector 161, and then electrically connected to the universal motherboard 16 through the embedded display port connector 161. Based on this, the panel power management module 20 provides power management required for the first type display panel 121 according to the universal motherboard 16, so that the first type display panel 121 (the organic light-emitting diode panel) runs normally.

In an embodiment, since the panel power management module 20 is an independent module and a non-fixed mobile device, the panel power management module is mounted at any vacant position in the electronic device 10. In an embodiment, the panel power management module 20 is mounted in a frame of the first type display panel 121.

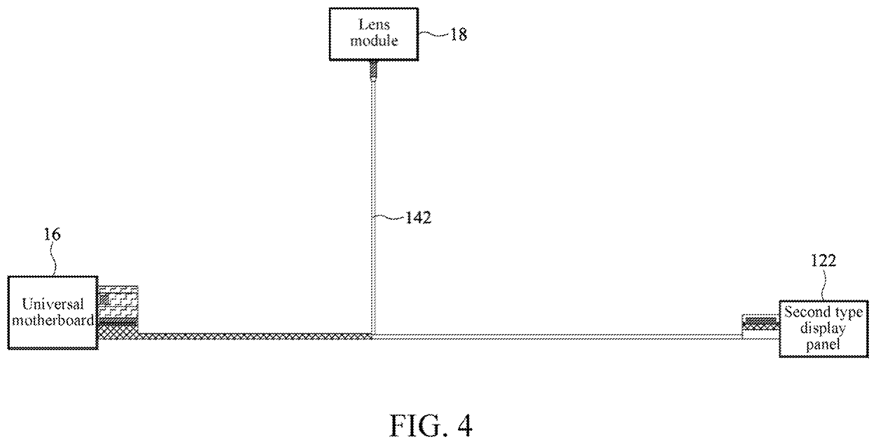

Since the second type display panel 122 is a display panel 12 that does not require the panel power management module 20, in an embodiment, the second type display panel 122 is an in-plane-switching (IPS) liquid crystal panel. As shown in FIG. 2 and FIG. 4, the electronic device 10 includes the second type display panel 122, the second transmission line 142, the universal motherboard 16, and the lens module 18. The universal motherboard 16 is connected to the second type display panel 122 and the lens module 18 through the second transmission line 142. The second transmission line 142 is an embedded display port (EDP) transmission line, and the universal motherboard 16 is provided with an embedded display port connector 161 correspondingly, so that the second transmission line 142 is connected to the embedded display port connector 161, and then electrically connected to the universal motherboard 16 through the embedded display port connector 161. Based on this, in order to make the second type display panel 122 (the in-plane-switching liquid crystal panel) run normally, it is only necessary to connect the universal motherboard 16 to the second type display panel 122.

In an embodiment, referring to FIG. 1 and FIG. 3 together, the first transmission line 141 is the embedded display port transmission line, and further includes a power cable and a signal cable, so that the first transmission line 141 should allow a corresponding current and signal speed. Therefore, the universal motherboard 16 transmits power and signals to the first type display panel 121, the lens module 18, and the panel power management module 20 through the first transmission line 141, and the panel power management module 20 transmits power and signals to the first type display panel 121 through the first transmission line 141. Similarly, referring to FIG. 2 and FIG. 4 together, the second transmission line 142 is an embedded display port transmission line, and further includes a power cable and a signal cable, so that the second transmission line 142 allows a corresponding current and signal speed. Therefore, the universal motherboard 16 transmits power and signals to the second type display panel 122 and the lens module 18 through the second transmission line 142. The power cable usually uses American Wire Gauge (AWG) Teflon wire (Teflon wire), and the signal cable usually uses American Wire Gauge (AWG) coaxial wire (Coaxial wire).

Furthermore, as shown in FIG. 1 and FIG. 2, in order to make the same universal motherboard 16 compatible with the first type display panel 121 and the second type display panel 122 of two completely different architectures, the embedded display port connector 161 on the universal motherboard 16 is designed with a common circuit and multi-functional pin assignment. Therefore, for the pin assignment of the embedded display port connector 161, refer to Table 1 below.

TABLE 1

| Pin | Signal name | American Wire Gauge (AWG) |
|---|---|---|
| 1 | +3V_CAM | Teflon wire |
| 2 | USB_PN6_R | Coaxial cable |
| 3 | USB_PP6_R | Coaxial cable |
| 4 | GND | |
| 5 | AMIC_DMIC_DATA_L | Coaxial cable |
| 6 | AMIC_DMIC_CLK_AGND | Coaxial cable |
| 7 | GND | |
| 8 | EDP_L3_N_C | Coaxial cable |
| 9 | EDP_L3_P_C | Coaxial cable |
| 10 | GND | |
| 11 | EDP_L2_N_C | Coaxial cable |
| 12 | EDP_L2_P_C | Coaxial cable |
| 13 | GND | |
| 14 | EDP_L1_N_C | Coaxial cable |
| 15 | EDP_L1_P_C | Coaxial cable |
| 16 | GND | |
| 17 | EDP_L0_N_C | Coaxial cable |
| 18 | EDP_L0_P_C | Coaxial cable |
| 19 | GND | |
| 20 | EDP_AUXP_C | Coaxial cable |
| 21 | EDP_AUXN_C | Coaxial cable |
| 22 | GND | |
| 23 | NC | |
| 24 | +3V_EDP | Teflon wire |
| 25 | +3V_EDP | Teflon wire |
| 26 | +3V_EDP | Teflon wire |
| 27 | +3V_EDP | Teflon wire |
| 28 | NC | |
| 29 | BL_EN_1V8 | Teflon wire |
| 30 | EDP_HPD_CON_X1 | Teflon wire |
| 31 | BL_EN3V3 | Teflon wire |
| 32 | EDP_BRIGHTNESS | Teflon wire |
| 33 | GND | |
| 34 | GND | |
| 35 | GND | |
| 36 | NC | |
| 37 | +LED_VCC_INV | Teflon wire |
| 38 | +LED_VCC_INV | Teflon wire |
| 39 | +LED_VCC_INV | Teflon wire |
| 40 | +LED_VCC_INV | Teflon wire |

Therefore, as shown in FIG. 1 and FIG. 2, in the disclosure, the first transmission line 141 is used with the independent panel power management module 20 for the first type display panel 121 (the organic light-emitting diode panel), and the second transmission line 142 is used for the second type display panel 122 (the in-plane-switching liquid crystal panel), without changing the universal motherboard 16. The same universal motherboard 16 is shared, and the panel power management module 20 does not need to be arranged on the universal motherboard 16, to save space. If the second type display panel 122 (the in-plane-switching liquid crystal panel) is used, the panel power management module 20 is further omitted.

To sum up, the electronic device in the disclosure uses a universal motherboard to match different transmission lines without replacing the motherboard, so that the same motherboard is compatible with display panels of two different architectures. In this way, an area of the motherboard is optimized. In addition, with an independent design of the panel power management module, the motherboard is applicable to a wider range. Therefore, in this case, the area of the motherboard has higher utilization, and subsequently designed models are also allowed to share the panel power management module, so that different models have better commonality.

The embodiments described above are only used for explaining the technical ideas and characteristics of the disclosure to enable a person skilled in the art to understand and implement the content of the disclosure, and are not intended to limit the patent scope of the disclosure. That is, any equivalent change or modification made according to the spirit disclosed in the disclosure shall still fall within the patent scope of the disclosure.

What is claimed is:

1. An electronic device, comprising:
a display panel, which is a first type display panel or a second type display panel;
a transmission line, which is a first transmission line or a second transmission line; and
a universal motherboard, connected to the first type display panel through the first transmission line, or connected to the second type display panel through the second transmission line, wherein
in a case that the display panel is the first type display panel, a panel power management module is connected to the universal motherboard and the first type display panel through the first transmission line, so that the panel power management module provides power management required for the first type display panel according to the universal motherboard.

2. The electronic device according to claim 1, wherein the first transmission line and the second transmission line are each an embedded display port (EDP) transmission line.

3. The electronic device according to claim 2, wherein the universal motherboard is provided with an embedded display port connector, so that the first transmission line or the second transmission line is connected to the embedded display port connector.

4. The electronic device according to claim 1, further comprising a lens module, connected to the universal motherboard through the first transmission line or the second transmission line.

5. The electronic device according to claim 1, wherein the first type display panel is an organic light-emitting diode (OLED) panel.

6. The electronic device according to claim 1, wherein the second type display panel is an in-plane-switching (IPS) liquid crystal panel.

7. The electronic device according to claim 1, wherein the first transmission line further comprises a power cable and a signal cable.

8. The electronic device according to claim 1, wherein the second transmission line further comprises a power cable and a signal cable.

9. The electronic device according to claim 1, wherein the panel power management module is located in a frame of the first type display panel.

10. The electronic device according to claim 1, wherein the electronic device is a notebook computer.
